(19) United States
(12) Patent Application Publication
(10) Pub. No.: US 2012/0293196 A1
(43) Pub. Date: Nov. 22, 2012

(54) TEST KEY STRUCTURE FOR MONITORING GATE CONDUCTOR TO DEEP TRENCH MISALIGNMENT AND TESTING METHOD THEREOF

(75) Inventors: Ping Hsu, Taoyuan County (TW); Yi-Nan Chen, Taoyuan County (TW); Hsien-Wen Liu, Taoyuan County (TW)

(73) Assignee: NANYA TECHNOLOGY CORPORATION, Taoyuan (TW)

(21) Appl. No.: 13/111,714

(22) Filed: May 19, 2011

(51) Int. Cl. G01R 31/26

(52) U.S. Cl. 324/762.01

(57) ABSTRACT

The disclosure provides a test key structure for monitoring gate conductor to deep trench misalignment and a testing method thereof. The test key structure for monitoring gate conductor to deep trench misalignment includes: a deep trench capacitor structure comprising a plurality of parallel deep trench capacitor lines and a deep trench capacitor connect; a buried strap out-diffusion adjacent to a first side of the deep trench capacitor line; a first gate conductor structure comprising a plurality of parallel first gate conductor lines and a first gate conductor connect, wherein each first gate conductor line is disposed directly over the corresponding deep trench capacitor line; and a second gate conductor structure comprising a plurality of parallel second gate conductor lines and a second gate conductor connect, wherein the first gate conductor lines are electrically connected to each other via the second gate conductor connect, and wherein the first gate conductor lines and the second gate conductor lines are parallel to each other, and the first gate conductor lines and the second gate conductor lines are arranged alternately.

### BACKGROUND

1. Technical Field

The present invention relates to a test key structure for monitoring gate conductor to deep trench (GC-DT) misalignment and a testing method thereof, and more particularly, to a test key structure for determining the left-shift of a gate conductor or right-shift of a gate conductor in the fabrication of a trench device with single-side buried strap and a testing method thereof.

2. Description of the Related Art

In semiconductor fabrication, a semiconductor device or an integrated circuit (IC) is continuously tested during every step of the fabrication process so as to maintain a required fabrication quality of a semiconductor. Ordinarily, a testing circuit is simultaneously fabricated with an actual device so that the quality of the actual device can be assessed by the performance of the testing circuit. The quality of the actual device therefore can be well controlled. Typically, such testing circuit, which is also referred to as “test key”, is disposed on a peripheral area of each chip or die.

FIG. 1 is a top view of a part of a conventional layout 10 of a trench capacitor DRAM device during the fabrication. FIG. 2 is a schematic cross-sectional diagram showing the test key structure along line 2-2′ of FIG. 1. As shown in FIG. 1, the layout 10 comprises a plurality of deep trench capacitors DT₀, DT₁, DT₂, DT₃, DT₄, DT₅, and DT₆. The gate conductor (GC) lines including GC₀, GC₁, GC₂, GC₃, and GC₄, are orthogonal to the overlying bit lines BL₀, BL₁, and BL₂. The deep trench capacitors DT₀, DT₁, DT₂, DT₃, DT₄, DT₅, and DT₆ of the layout 1 are fabricated simultaneously with the deep trench capacitors arranged in the memory array using the same fabrication processes. Therefore, the structures of each of the deep trench capacitors DT₀, DT₁, DT₂, DT₃, DT₄, DT₅, and DT₆ in the memory array are substantially the same. Basically, as shown in FIG. 2, each of the deep trench capacitors DT₂, and DT₃, which are embedded into a main surface of a silicon substrate 5, includes a shallow trench isolation (STI) 11, and a single side buried strap (SSBS) 12. Heavily doped sources/drains 13 are implanted into the silicon substrate 5 at both sides of each of the deep trench capacitors DT₂, and DT₃. A buried strap out-diffusion 20 is implanted into the silicon substrate 5 at the side adjacent to the single side buried strap (SSBS) 12 of the deep trench capacitors DT₂, and DT₃. A cap insulation layer 14 is disposed on the deep trench capacitors DT₂, and DT₃ and the top surface of the substrate 5. The plurality of gate conductor (GC) lines including GC₀, GC₁, GC₂, GC₃, and GC₄ are arranged in a column on the top surface of the silicon substrate 5. The gate conductor GC₀ is disposed on the cap insulation layer 14 directly over the deep trench capacitor DT₂. The gate conductor GC₁ is disposed on the cap insulation layer 14 between the deep trench capacitors DT₂ and DT₃. The gate conductor GC₂ is disposed on the cap insulation layer 14 directly over the deep trench capacitor DT₃. The gate conductor GC₄ is disposed on the cap insulation layer 14 between the deep trench capacitors DT₃ and DT₄. Each of the bit lines BL₀, BL₁, and BL₂ are electrically connected to a source/drain region of a corresponding cell select transistor through a bit line contact (CB) 15. The bit line contacts are separated from each other by a dielectric layer 16.

As shown in FIG. 2, according to the prior art method, to assess gate conductor to deep trench (GC-DT) misalignment, the threshold voltage of the gate conductor GC₀ and gate conductor GC₁ is measured, as known to those skilled in the art. However, the prior art GC-DT misalignment evaluation method is not accurate. When no gate conductor to deep trench (GC-DT) misalignment is present, the threshold voltage of the gate conductor GC₀ and gate conductor GC₁ is defined as a standard value Vₜₕ. When a right-shift of a gate conductor is present, the threshold voltage (VTH) of the measured gate conductor GC₀ and gate conductor GC₁ is less than the standard value Vₜₕ. Unfortunately, when the left-shift of a gate conductor is present, the measured threshold voltage (V_{TH}) of the gate conductor GC₀ and gate conductor GC₁ is substantially equal to the standard value Vth. Therefore, it is difficult for an inspector, to judge whether the gate conductor to deep trench (GC-DT) is misaligned, merely according to the measured threshold voltage data. Consequently, there is a need to provide an improved wafer acceptance testing method for accurately monitoring gate conductor to deep trench (GC-DT) misalignment.

### SUMMARY

The disclosure provides a test key structure for monitoring gate conductor to deep trench misalignment, comprising: a deep trench capacitor structure comprising a plurality of parallel deep trench capacitor lines and a deep trench capacitor connect, wherein the deep trench capacitor lines are electrically connected to each other via the deep trench capacitor connect; a buried strap out-diffusion adjacent to a first side of the deep trench capacitor line, wherein the deep trench capacitor line has a second side opposite to the first side, and there is no buried strap out-diffusion adjacent to the second side; a first gate conductor structure comprising a plurality of parallel first gate conductor lines and a first gate conductor connect, wherein the first gate conductor lines are electrically connected to each other via the first gate conductor connect, and wherein each first gate conductor line is disposed directly over the corresponding deep trench capacitor line; and a second gate conductor structure comprising a plurality of parallel second gate conductor lines and a second gate conductor connect, wherein the first gate conductor lines are electrically connected to each other via the second gate conductor connect, and wherein the first gate conductor lines and the second gate conductor lines are parallel to each other, and the first gate conductor lines and the second gate conductor lines are arranged alternately.

The disclosure also provides a testing method for monitoring gate conductor to deep trench misalignment, comprising: providing the aforementioned test key structure; measuring the first capacitance between the first gate conductor line and the deep trench capacitor line and the second capacitance between the second gate conductor line and the buried strap out-diffusion; and comparing the first capacitance with a first reference information, and comparing the second capacitance with a second reference information.

Particularly, the first reference information means the capacitance between the first gate conductor line and the deep trench capacitor line when no gate conductor to deep trench misalignment has occurred; and the second reference information means the capacitance between the second gate conductor line and the buried strap out-diffusion when no gate conductor to deep trench misalignment has occurred.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 is a plan view showing a portion of the layout of a trench capacitor DRAM array;

FIG. 2 is a schematic cross-sectional diagram along line 2-2′ of FIG. 1;

FIG. 3 is a plan view of a test key layout for monitoring the gate conductor to deep trench (GC-DT) misalignment in accordance with an embodiment of the disclosure;

FIG. 4 is a schematic cross-sectional diagram along line 4-4′ of FIG. 3; and

FIGS. 5 and 6 are schematic cross-sectional diagrams of the test key layout in accordance with an embodiment of the disclosure when the gate conductor to deep trench (GC-DT) misalignment has occurred.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

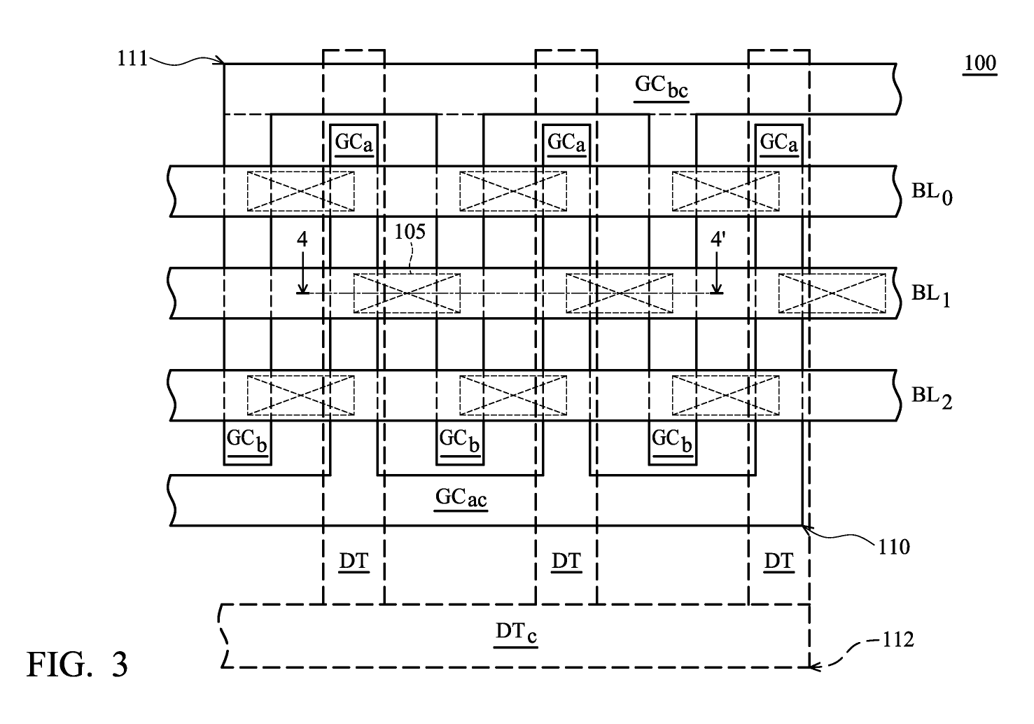

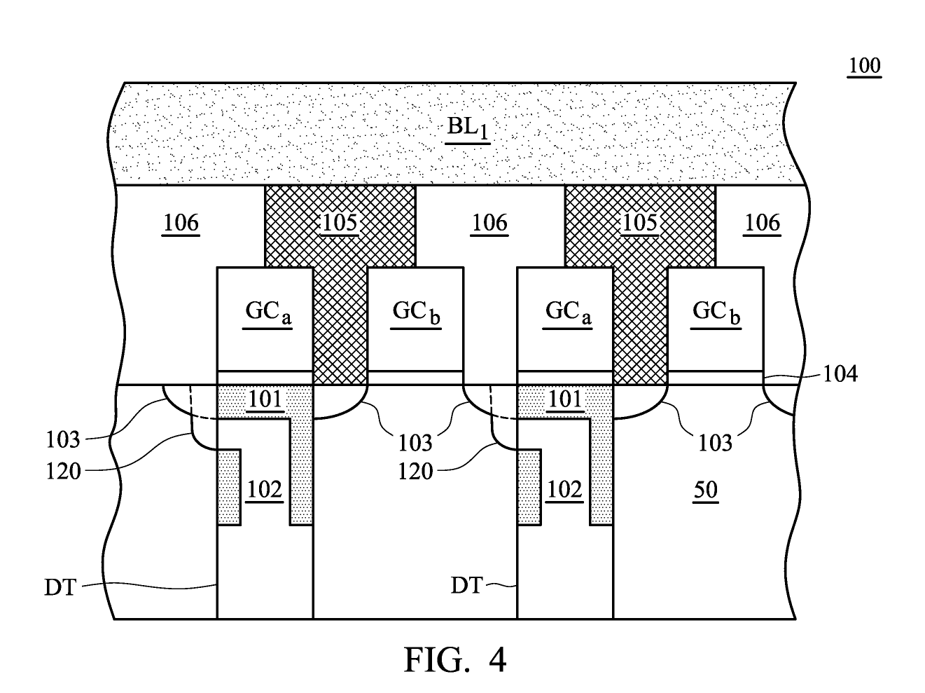

Please refer to FIG. 3 and FIG. 4. FIG. 3 is a plan view of a test key layout 100 for monitoring gate conductor to deep trench (GC-DT) misalignment in accordance with a preferred embodiment of the disclosure. FIG. 4 is a schematic cross-sectional diagram along line 4-4′ of FIG. 3.

As shown in FIGS. 3 and 4, the test key layout 100 includes a plurality of first gate conductor lines GCₐ and a plurality of second gate conductor lines GC_{b}. The structure of the first gate conductor lines GCₐ and the second gate conductor lines GC_{b} may include metal gates and polysilicon/silicide/silicon nitride stack gates, but are not limited thereto. Particularly, the first gate conductor lines GCₐ and the second gate conductor lines GC_{b} are parallel to each other, and the first gate conductor lines GCₐ and the second gate conductor lines GC_{b} are arranged alternately. For example, the first gate conductor line GCₐ is disposed between two adjacent second gate conductor lines GC_{b}, and the second gate conductor line GC_{b} is disposed between two adjacent first gate conductor lines GCₐ. Further, the first gate conductor lines GCₐ do not directly connect to the second gate conductor lines GC_{b}. The plurality of first gate conductor lines GCₐ are electrically connected to each other via a first gate conductor connect GC_{ac}, and the plurality of second gate conductor lines GC_{b} are electrically connected to each other via a second gate conductor connect GC_{bc}. As shown in FIG. 3, the plurality of first gate conductor lines GC_{a and the first gate conductor connect GC}_{ac} compose a first gate conductor structure 110, wherein the first gate conductor structure 110 is comb-shaped. Meanwhile, the plurality of second gate conductor lines GC_{b} and the second gate conductor connect GC_{bc} compose a second gate conductor structure 111, wherein the second gate conductor structure 111 is also comb-shaped. A voltage signal can be applied to the first gate conductor lines GCₐ through the first gate conductor connect GC_{ac}. Similarly, A voltage signal can be applied to the second gate conductor lines GC_{b} through the second gate conductor connect GC_{bc}. As shown in FIG. 3, rows of bit lines BL0, BL1, and BL2 are patterned on a dielectric layer 106 disposed on the substrate 50. The bit lines BL0, BL1, and BL2 are orthogonal to the underlying columns of the first gate conductor lines GCₐ and the second gate conductor lines GC_{b}. The dielectric layer 106 may include a silicon nitride liner and a borophosphosilicate glass (BPSG) layer. The dielectric layer 106 fills the inter-spacings between the first gate conductor lines GCₐ and the second gate conductor lines GC_{b}. A conventional lithographic and an etching process can be performed to form bit line contacts (CB) 105 within the dielectric layer 150. The bit line contacts (CB) 105 are directly connected to the bit lines BL₀, BL₁, and BL₂.

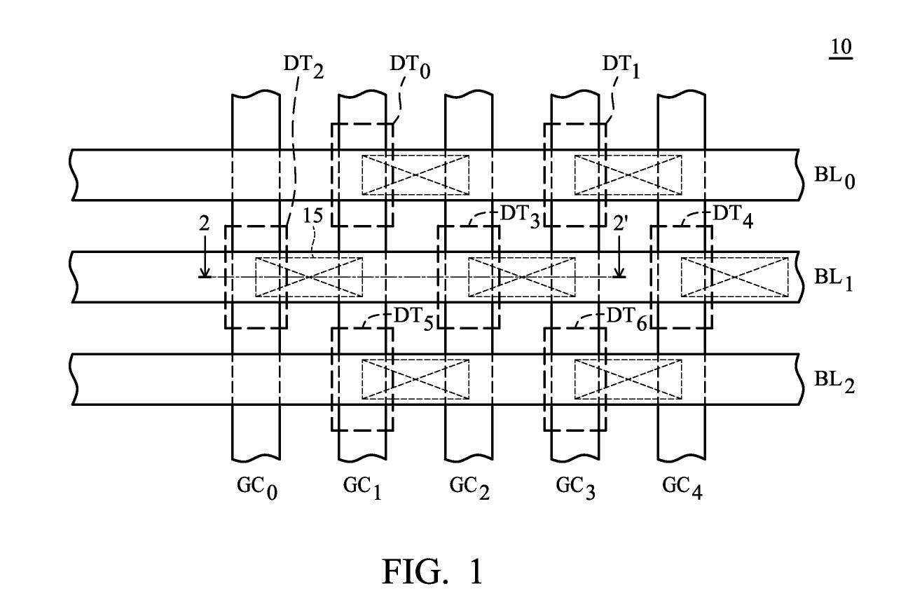

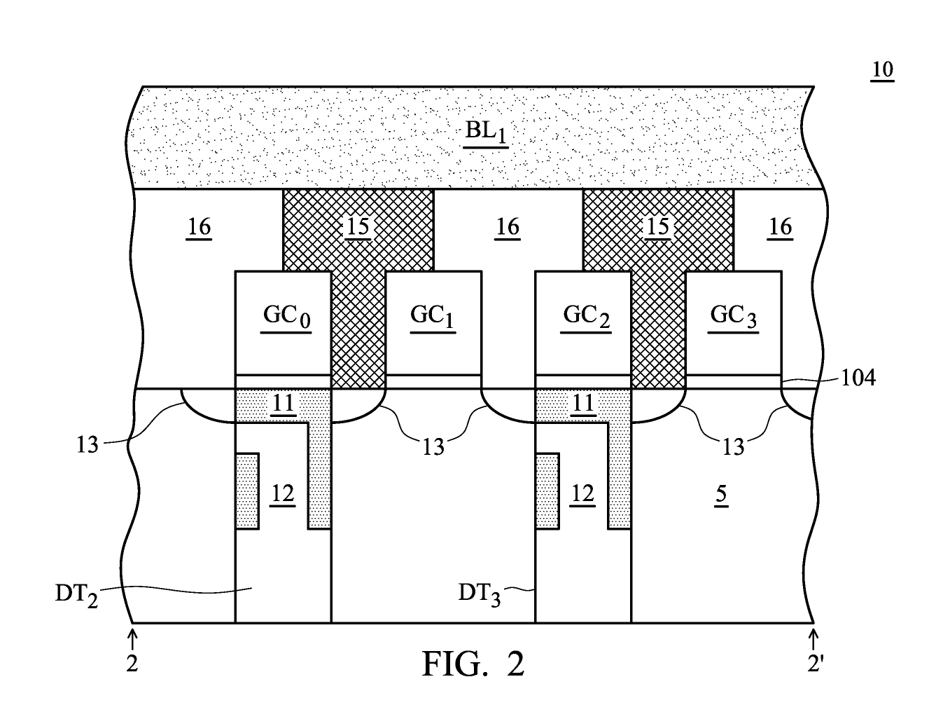

As shown in FIG. 3, the test key layout 100 further includes a plurality of deep trench capacitor lines DT, wherein the plurality of deep trench capacitor lines DT are parallel to the first gate conductor lines GCₐ and the second gate conductor lines GC_{b} in plan view. The plurality of deep trench capacitor lines DT are formed within the substrate 50. The plurality of deep trench capacitor lines DT are disposed directly under the first gate conductor lines GCₐ, or the plurality of deep trench capacitor lines DT are disposed directly under the second gate conductor lines GC_{b}. It should be noted that the deep trench capacitor lines DT would not be disposed directly under the first gate conductor lines GCₐ and the second gate conductor lines GC_{b} simultaneously. In the embodiment of FIGS. 3 and 4, the plurality of deep trench capacitor lines DT is disposed directly and correspondingly under the plurality of first gate conductor lines GCₐ. As shown in FIG. 3, the plurality of deep trench capacitor lines DT are electrically connected to each other via a deep trench capacitor connect DT_{c}, and the deep trench capacitor lines DT and the deep trench capacitor connect DT_{c} compose a deep trench capacitor structure 112, wherein the deep trench capacitor structure 112 is comb-shaped. In the disclosure, the conventional deep trench capacitor as shown in FIG. 1 are replaced with the deep trench capacitor lines DT. The deep trench capacitor lines DT of the test key 100 are fabricated simultaneously and have the same dimensions. As shown in FIG. 4, the deep trench capacitor line DT includes a shallow trench isolation (STI) 101, and a polysilicon filler (including a single side buried strap (SSBS)) 102. The heavily doped source/drain 103 is implanted into the substrate 50 after the formation of the first gate conductor lines GCₐ and the second gate conductor lines GC_{b}. It should be noted that the heavily doped source/drain 103 is disposed at both sides of each of the deep trench capacitor lines DT. A buried strap out-diffusion 120 is implanted into the substrate 50 at the side adjacent to the single side buried strap (SSBS) of the deep trench capacitor lines DT. Namely, the buried strap out-diffusion 120 is just disposed at one side of the trench capacitor line DT. A cap insulation layer 104 is disposed directly under the first gate conductor lines GCₐ and the second gate conductor lines GC_{b}, separating the gate conductor lines from the deep trench capacitor lines.

The disclosure is characterized in that, by means of the first gate conductor structure 111, the second gate conductor structure 111, the deep trench capacitor structure 112, the capacitance between the deep trench capacitor lines DT and the first gate conductor lines GCₐ and the capacitance between the deep trench capacitor lines DT and the second gate conductor lines GC_{b} can be measured. The testing method for monitoring gate conductor to deep trench (GC-DT) misalignment and the use of a test key structure of the disclosure will be demonstrated with reference to FIGS. 4-6.

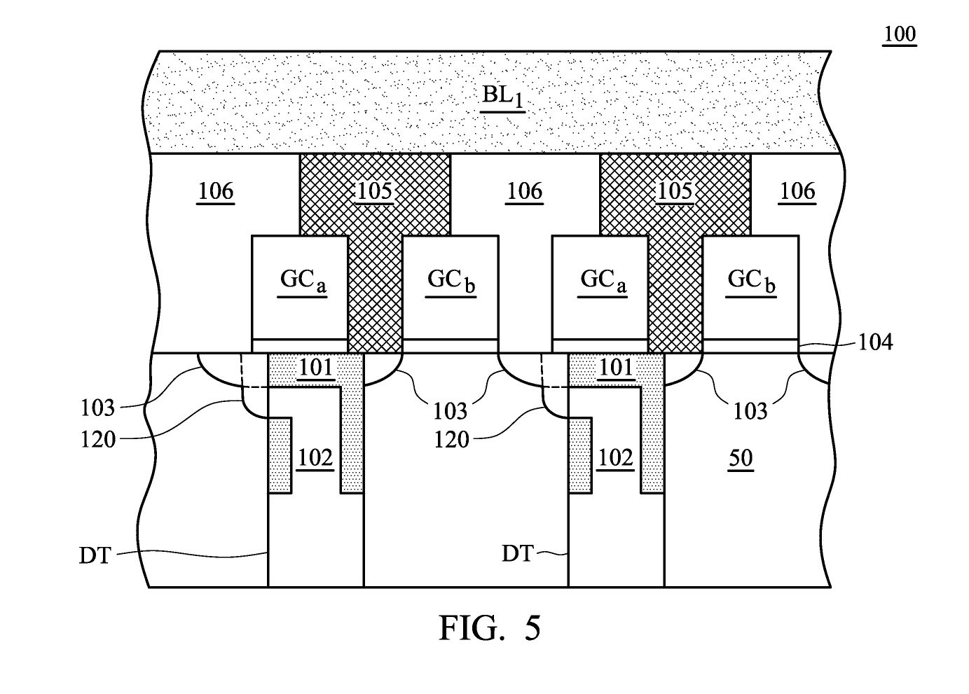

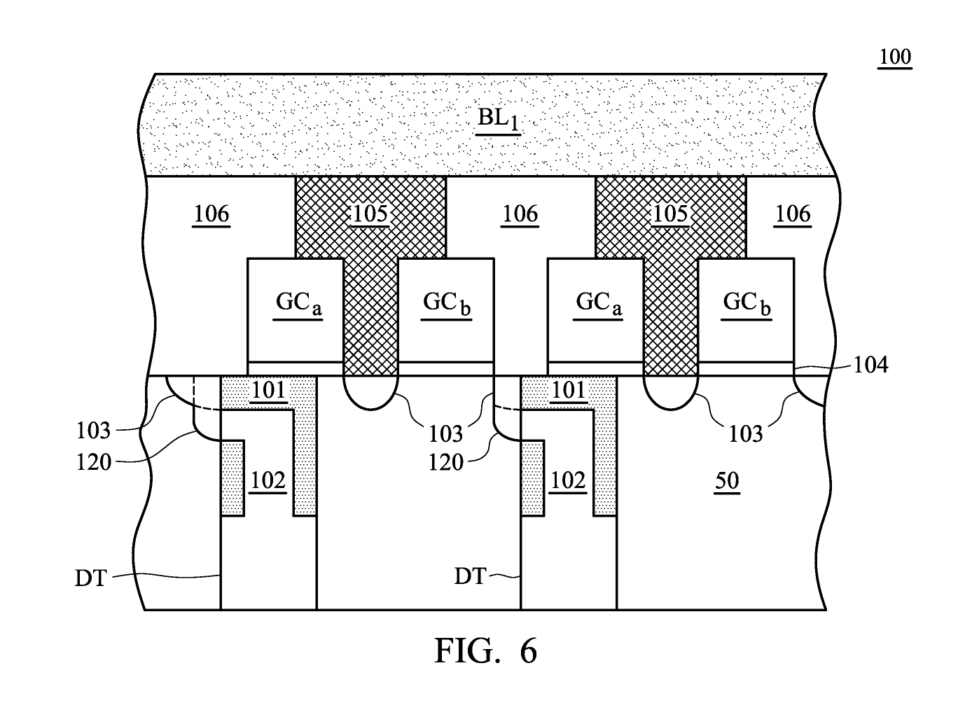

FIG. 4 demonstrates an ideal case in which the first gate conductor lines GCₐ and the deep trench capacitor lines DT are aligned. Meanwhile, FIG. 5 demonstrates a gate conductor to deep trench (GC-DT) misalignment case, wherein the first gate conductor lines GCₐ and the second gate conductor lines GC_{b} are misaligned toward the right side of the deep trench capacitor lines DT, causing a right-shift of a gate conductor. Further, FIG. 6 demonstrates a gate conductor to deep trench (GC-DT) misalignment case, wherein the first gate conductor lines GCₐ and the second gate conductor lines GC_{b} are misaligned toward the left side of the deep trench capacitor lines DT, causing a left-shift of a gate conductor.

As mentioned, the first gate conductor lines GCₐ definition of a memory array is carried out simultaneously with the first gate conductor structure 110 in the test key. Therefore, if there is a gate conductor to deep trench (GC-DT) misalignment in the memory array, the misalignment will also occur in the test key. In the embodiments of the invention, the prior art threshold voltage measure and evaluation methods which are subjected to interference is not used. Instead, a more accurate capacitance measure and evaluation method is employed.

According to the capacitance measure and evaluation method of the disclosure, the first gate conductor line GCₐ serves as a top electrode of a first capacitor. The second electrode of the first capacitor is the polysilicon 102 of the deep trench capacitor lines DT. The first capacitor between the first gate conductor line GCₐ and the deep trench capacitor line DT has a capacitance C₁ (the capacitance C₁ is measured by providing a first voltage to the first gate conductor line GCₐ and providing a second voltage to the deep trench capacitor lines DT). Meanwhile, the second gate conductor line GC_{b} serves as a top electrode of a second capacitor. The second electrode of the second capacitor is the buried strap out-diffusion 120 adjacent to the deep trench capacitor line DT. The second capacitor between the second gate conductor line GC_{b} and the buried strap out-diffusion 120 has a capacitance C₂ (the capacitance C₂ is measured by providing a first voltage to the second gate conductor line GC_{b} and providing a second voltage to the buried strap out-diffusion 120). Since the second gate conductor line GC_{b} does not overlap with the buried strap out-diffusion 120, the capacitance C₂ of the second capacitor is approximately equal to zero.

FIG. 5 demonstrates a gate conductor to deep trench (GC-DT) misalignment case, wherein the first gate conductor lines GCₐ and the second gate conductor lines GC_{b} are misaligned toward the right side of the deep trench capacitor lines DT. As shown in FIG. 5, since the right-shift of a gate conductor occurs, the overlapped area between the first gate conductor line GCₐ and the polysilicon 102 of the deep trench capacitor line DT is reduced. Therefore, the capacitance C_{R1} of the first capacitor of FIG. 5 should be less than the capacitance C₁ (i.e. C₁>C_{R1}). Meanwhile, since the second gate conductor line GC_{b} is moved toward the right side of the deep trench capacitor line DT, the second gate conductor line GC_{b} is closer to the buried strap out-diffusion 120 and/or may be further partially overlapped with the buried strap out-diffusion 120. Therefore, the capacitance C_{R2} of the second capacitor of FIG. 5 should be equal to or larger than (when the second gate conductor line GC_{b} partially overlapping with the buried strap out-diffusion 120) the capacitance C₂ (i.e. C₂≦C_{R2}).

FIG. 6 demonstrates a gate conductor to deep trench (GC-DT) misalignment case, wherein the first gate conductor lines GCₐ and the second gate conductor lines GC_{b} are misaligned toward the left side of the deep trench capacitor lines DT. As shown in FIG. 6, although the overlapped area between the first gate conductor line GCₐ and the polysilicon 102 of the deep trench capacitor line DT is reduced when the left-shift of a gate conductor occurs, but the first gate conductor line GCₐ further partially overlaps with the buried strap out-diffusion 120. Therefore, the capacitance C_{L}, of the first capacitor of FIG. 6 should be larger than the capacitance C₁ (i.e. C₁<C_{L1}). Meanwhile, the second gate conductor line GC_{b} is shifted away from the buried strap out-diffusion 120 when the second gate conductor line GC_{b} is moved toward the left side of the deep trench capacitor line DT. Therefore, the capacitance C_{L2} of the second capacitor of FIG. 6 should be equal to the capacitance C₂ (i.e. C₂=C_{L2}).

From the above, the test key structure of the disclosure can be used to monitor gate conductor to deep trench (GC-DT) misalignment by measuring the capacitance data between the first gate conductor line GCₐ and the deep trench capacitor line DT and the capacitance data between the second gate conductor line GC_{b} and the buried strap out-diffusion 120. Moreover, when the gate conductor to deep trench (GC-DT) misalignment has occurred, the test key structure of the disclosure can further be used to determine whether the gate conductor line has shifted toward the right or the left of the deep trench.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A test key structure for monitoring gate conductor to deep trench misalignment, comprising:
a deep trench capacitor structure comprising a plurality of parallel deep trench capacitor lines and a deep trench capacitor connect, wherein the deep trench capacitor lines are electrically connected to each other via the deep trench capacitor connect;
a buried strap out-diffusion adjacent to a first side of the deep trench capacitor line, wherein the deep trench capacitor line has a second side opposite to the first side, and there is no buried strap out-diffusion adjacent to the second side;
a first gate conductor structure comprising a plurality of parallel first gate conductor lines and a first gate conductor connect, wherein the first gate conductor lines are electrically connected to each other via the first gate conductor connect, and wherein each first gate conductor line is disposed directly over the corresponding deep trench capacitor line; and
a second gate conductor structure comprising a plurality of parallel second gate conductor lines and a second gate conductor connect, wherein the first gate conductor lines are electrically connected to each other via the second gate conductor connect, and wherein the first gate conductor lines and the second gate conductor lines are parallel to each other, and the first gate conductor lines and the second gate conductor lines are arranged alternately.

2. The test key structure for monitoring gate conductor to deep trench misalignment as claimed in claim 1, wherein the second gate conductor does not overlap with the deep trench capacitor line.

3. The test key structure for monitoring gate conductor to deep trench misalignment as claimed in claim 1, wherein the deep trench capacitor structure is embedded in a substrate.

4. The test key structure for monitoring gate conductor to deep trench misalignment as claimed in claim 1, further comprising:
a plurality of bit lines orthogonal to the underlying columns of the first gate conductor lines and the second gate conductor lines.

5. The test key structure for monitoring gate conductor to deep trench misalignment as claimed in claim 1, wherein the deep trench capacitor structure is comb-shaped.

6. The test key structure for monitoring gate conductor to deep trench misalignment as claimed in claim 1, wherein the first gate conductor structure is comb-shaped.

7. The test key structure for monitoring gate conductor to deep trench misalignment as claimed in claim 1, wherein the second gate conductor structure is comb-shaped.

8. The test key structure for monitoring gate conductor to deep trench misalignment as claimed in claim 1, wherein the first gate conductor structure and the second gate conductor structure are not electrically connected to each other.

9. A testing method for monitoring gate conductor to deep trench misalignment, comprising:
providing a test key structure, wherein the test key structure comprises
a deep trench capacitor structure comprising a plurality of parallel deep trench capacitor lines and a deep trench capacitor connect, wherein the deep trench capacitor lines are electrically connected to each other via the deep trench capacitor connect;
a buried strap out-diffusion adjacent to a first side of the deep trench capacitor line, wherein the deep trench capacitor line has a second side opposite to the first side, and there is no buried strap out-diffusion adjacent to the second side;
a first gate conductor structure comprising a plurality of parallel first gate conductor lines and a first gate conductor connect, wherein the first gate conductor lines are electrically connected to each other via the first gate conductor connect, and wherein each first gate conductor line is disposed directly over the corresponding deep trench capacitor line; and
a second gate conductor structure comprising a plurality of parallel second gate conductor lines and a second gate conductor connect, wherein the first gate conductor lines are electrically connected to each other via the second gate conductor connect, and wherein the second gate conductor does not overlap with the deep trench capacitor line, and wherein the first gate conductor lines and the second gate conductor lines are parallel to each other, and the first gate conductor lines and the second gate conductor lines are arranged alternately; and
measuring a first capacitance between the first gate conductor line and the deep trench capacitor line and a second capacitance between the second gate conductor line and the buried strap out-diffusion; and
comparing the first capacitance with a first reference information, and comparing the second capacitance with a second reference information.

10. The testing method as claimed in claim 9, wherein the second gate conductor does not overlap with the deep trench capacitor line.

11. The testing method as claimed in claim 9, wherein the deep trench capacitor structure is embedded in a substrate.

12. The testing method as claimed in claim 9, further comprising:
a plurality of bit lines orthogonal to the underlying columns of the first gate conductor lines and the second gate conductor lines.

13. The testing method as claimed in claim 9, wherein the deep trench capacitor structure is comb-shaped.

14. The test key structure for monitoring gate conductor to deep trench misalignment as claimed in claim 1, wherein the first gate conductor structure is comb-shaped.

15. The testing method as claimed in claim 9, wherein the second gate conductor structure is comb-shaped.

16. The testing method as claimed in claim 9, wherein the first gate conductor structure and the second gate conductor structure are not electrically connected to each other.

17. The testing method as claimed in claim 9, wherein the first reference information means the capacitance between the first gate conductor line and the deep trench capacitor line when no gate conductor to deep trench misalignment has occurred.

18. The testing method as claimed in claim 9, wherein the second reference information means the capacitance between the second gate conductor line and the buried strap out-diffusion when no gate conductor to deep trench misalignment has occurred.

19. The testing method as claimed in claim 9, wherein the first capacitance is smaller than the first reference information, and the second capacitance is equal to or larger than the second reference information when a right-shift of a gate conductor occurs.

20. The testing method as claimed in claim 9, wherein the first capacitance is larger than the first reference information, and the second capacitance is equal to the second reference information when a left-shift of a gate conductor occurs.
